(19) United States
(12) Patent Application Publication
(10) Pub. No.: US 2020/0052697 A1
(43) Pub. Date: Feb. 13, 2020

(54) MECHANICAL SWITCHES FOR TFT DISPLAYS

(71) Applicant: Continental Automotive Systems, Inc., Auburn Hills, MI (US)

(72) Inventors: Jean-Christophe Deniau, Fenton, MI (US); David Muscat, Lake Orion, MI (US); Aruna Anand, Rochester, MI (US)

(21) Appl. No.: 16/533,299

(22) Filed: Aug. 6, 2019

Related U.S. Application Data
(60) Provisional application No. 62/715,410, filed on Aug. 7, 2018.

(51) Int. Cl. H03K 17/97; G06F 3/0362; G06F 3/01

(52) U.S. Cl. CPC H03K 17/97; G06F 3/016; G06F 3/0362

(57) ABSTRACT

A switch comprises a dielectric panel having first and second sides and a knob assembly mounted on the first side of the panel. The knob assembly includes a housing having first and second ends, a knob rotatably and translationally mounted to the housing at the first end, a shaft attached to the knob at a first end, and a permanent magnet attached to a second end of the shaft such that rotation of and translation of the knob produces a corresponding motion of the magnet. The switch also includes a sensor assembly located on the second side of the panel including at least one hall-effect sensor adjacent the panel. The knob assembly is mounted to the panel such that the at least one hall-effect sensor is located inside the magnetic field created by the magnet.

### CROSS REFERENCE TO RELATED APPLICATIONS

U.S. patent application claims the benefit of U.S. provisional patent application No. 62/715,410, filed Aug. 7, 2018 which is hereby incorporated by reference.

### BACKGROUND

Instrument panels in motor vehicles use displays to provide information that is typically related to items such as navigation, radio control, climate control, etc. Vehicles are commonly equipped with liquid-crystal displays (LCD) and thin-film-transistor liquid-crystal display (TFT). These displays typically use touch-screen controls, e.g. buttons, slides, rocker switches, etc. to provide a human-machine interface for controlling and navigation the information provided on the display. However, these switches may be difficult to operate, for example, while wearing gloves. Additionally, these virtual switches do not give any mechanical feedback; which is found to be a major drawback of these types of displays.

### SUMMARY

One general aspect comprises a switch including: a dielectric panel having first and second sides and a knob assembly mounted on the first side of the panel. The knob assembly includes a housing having first and second ends, a knob rotatably and translationally mounted to the housing at the first end, a shaft attached to the knob at a first end, and a permanent magnet attached to a second end of the shaft such that rotation of and translation of the knob produces a corresponding motion of the magnet. The switch also includes a sensor assembly located on the second side of the panel including at least one hall-effect sensor adjacent the panel. The knob assembly is mounted to the panel such that the at least one hall-effect sensor is located inside the magnetic field created by the magnet.

Implementations may include one or more of the following features. The switch where the at least one hall-effect sensor includes three hall-effect cells arranged in a perpendicular manner to one another.

The switch where the at least one hall-effect sensor is a plurality of hall-effect sensors arranged in an array on the second side of the panel such that the knob assembly may be positioned proximate to one of the plurality of hall-effect sensors.

The switch further including a second knob assembly mounted on the first side of the panel, the second knob assembly including: a second housing having first and second ends; a second knob rotatably and translationally mounted to the second housing at the first end; a second shaft attached to the second knob at a first end; and a second permanent magnet attached to a second end of the second shaft such that rotation of and translation of the second knob produces a corresponding motion of the second magnet. The switch may also include where the second knob assembly is mounted to the panel such that another of the plurality of hall-effect sensors is located inside the magnetic field created by the magnet of the second knob assembly.

The switch where the second magnet has a different magnetic strength than the first magnet.

The switch where the housing for the knob assembly is removably secured to the first side of the panel.

The switch further including a coil spring inside the housing and around the shaft, the spring providing a bias force to the shaft, which holds the magnet away from the hall-effect sensor.

One general aspect includes a method of providing control for an electronic display including: mounting a knob assembly on a first side of a panel where the knob assembly can provide rotational and translational movement to a magnet, sensing with a sensor assembly located on the second side of the panel movement of the magnet using at least one hall-effect sensor adjacent the panel where the knob assembly is mountable to the panel such that the at least one hall-effect sensor is located inside the magnetic field created by the magnet, and changing an image on the display in response to the sensed movement of the magnet.

Implementations may include one or more of the following features. The method where the at least one hall-effect sensor includes three hall-effect cells arranged in a perpendicular manner to one another.

The method where the at least one hall-effect sensor is a plurality of hall-effect sensors arranged in an array on the second side of the panel such that the knob assembly may be positioned proximate to one of the plurality of hall-effect sensors.

The method further including: mounting a second knob assembly on the first side of the panel where the second knob assembly can provide rotational and translational movement to a second magnet; sensing movement of the second magnet with another of the plurality of hall-effect sensors.

The method further including changing another portion of the image on the display in response to the sensed movement of the second magnet.

The method further including sensing a difference between the magnetic field produced by the first magnet and the magnetic field produced by a second magnet.

The method further including removably securing the housing to the first side of the panel. The switch where the shaft is configured to translate along an axis of the shaft.

Other objects, features and characteristics of the present invention, as well as the methods of operation and the functions of the related elements of the structure, the combination of parts and economics of manufacture will become more apparent upon consideration of the following detailed description and appended claims with reference to the accompanying drawings, all of which form a part of this specification. It should be understood that the detailed description and specific examples, while indicating the preferred embodiment of the disclosure, are intended for purposes of illustration only and are not intended to limit the scope of the disclosure.

### BRIEF DESCRIPTION OF THE FIGURES

FIG. 1 is a cross-sectional view of a first embodiment of a mechanical switch for a TFT display;

FIG. 2 is an exploded view of the first embodiment mechanical switch shown in FIG. 1; and

FIG. 3 is a cut-away view of a second embodiment of a mechanical switch and a display panel.

FIG. 4 is a schematic perspective view of a third embodiment of a mechanical switch and a display panel.

FIG. 5 is a cut-away view of the third embodiment of the mechanical switch and display panel.

FIG. 6 is a schematic view of an exemplary method for controlling a display with the mechanical switch described herein.

Like reference symbols in the various drawings indicate like elements.

### DETAILED DESCRIPTION

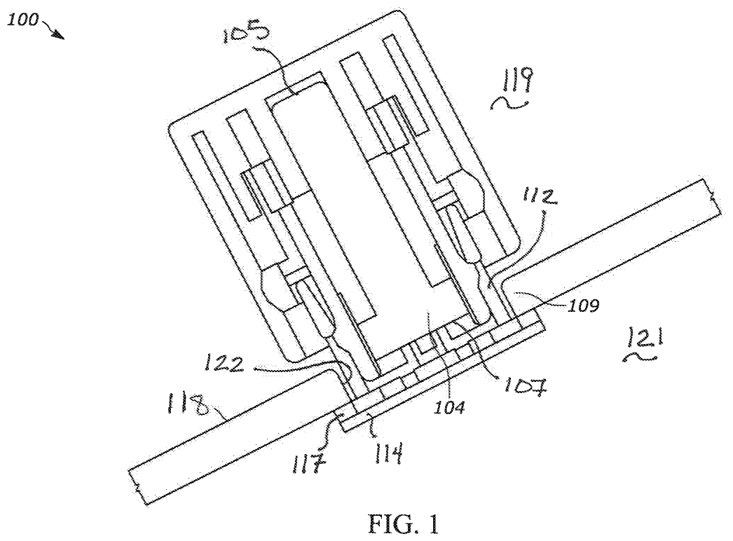

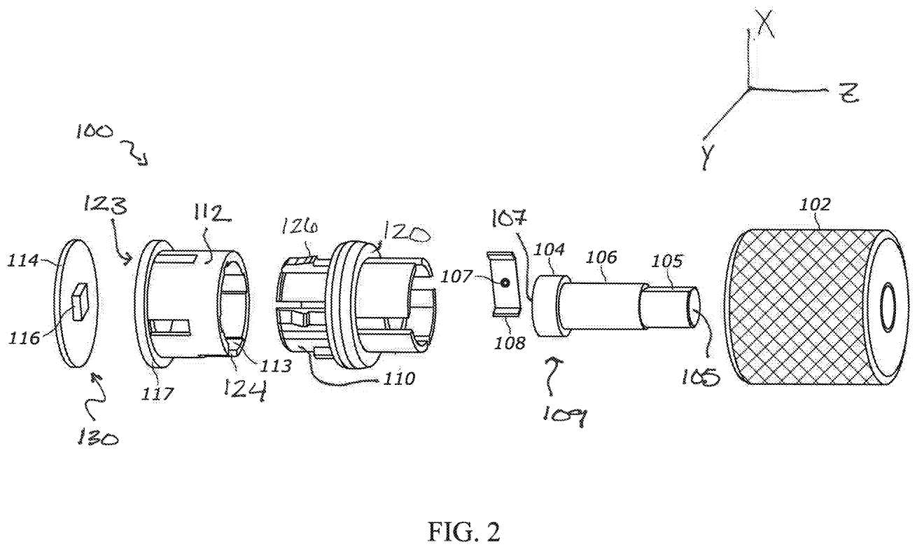

FIG. 1 is a cross-sectional view of a mechanical switch 100 for use with a TFT or LCD display. FIG. 2 is an exploded view of the same switch 100.

The switch assembly 100 is comprised of a knob 102, a magnet 104 mounted on a shaft106, a spring clip 108 between the shaft 106 and a housing 110. A bushing 112 is mounted on the housing 110 and supports a printed circuit board (PCB) 114 which includes a sensor 116, specifically a Hall effect sensor. The switch assembly 100 is mounted to a glass panel 118 which provides a display. The arrangement and operation of the switch assembly 100 are explained in greater detail below.

The knob 102 fits onto a first end 105 of the elongated shaft 106 using any conventional apparatus or method. A second or opposite end 107 of the shaft 106 is provided with the permanent magnet 104. The magnet 104 is applied to the second end 107 of the shaft 106 using an adhesive or mechanical attachment mechanism.

The magnet 104 is essentially torroidal in shape. The outside 109 of the torroid-shaped magnet 104 fits inside the inside diameter 111 of the housing 110. The housing 110 may have a cylindrical shape. The housing 110 has an exterior-located collar 120 which is sized and shaped to prevent the housing 110 from passing through or slipping through an opening 122 formed into a panel 118 of a TFT display device, not shown.

The bushing 112 has an inside diameter 113 and grooves or slots 124 which are sized and shaped to receive tabs 126 on the lower outside diameter 115 of the housing 110. The bushing 112 has a collar or shoulder 117 which holds the assembled bushing and housing in the opening 122 formed in the glass panel 118.

The shoulder-end 123 of the bushing 112 rides on or is closely spaced from the PCB 114 attached to which is the conventional Hall effect sensor 116. When the components shown in FIG. 2 are assembled as shown in FIG. 1, the knob is located on a first or top side 119 of the panel 118 and the bushing and sensor 116 are located on a second, opposing, bottom side 121 of the panel 118.

When assembled the magnet 104 is closely spaced away from the Hall effect sensor 116. Rotation of the magnet 104 by turning the knob 102 thus generates an electrically-measurable signal by the Hall effect sensor 116. Rotation of the knob 102 thus generates an electrical signal from the Hall-effect sensor 116 that can be used to control some external device. The signals from the Hall-effect sensor 116 are pulses, the rotation of the knob 102 thus effectively produces a signal essentially the same as that which would be provided by a mechanical switch.

The Hall-effect sensors 116 comprises an application specific integrated circuit (ASIC) 130 which includes up to three Hall-effect cells 132x, 132y, 132z. The Hell-effect cells are arranged in perpendicular orientation from one another such that can sense movement along the X,Y and Z-axes as shown. Therefore, as the control knob 102 is rotated about the z-axis the first two Hall-effect cells 132x, 132y can detect that movement based on the position of the magnet 104 in the X, Y planes. Additionally, when pressure is applied to the control knob 102 the spring 108 flexes allowing the knob 102 and magnet 104 to translate along the Z-axis which can be sensed by the third Hall-effect cell 132z. Thus, the Hall-effect sensor 116 can sense motion of the control knob 102 in three-dimensions.

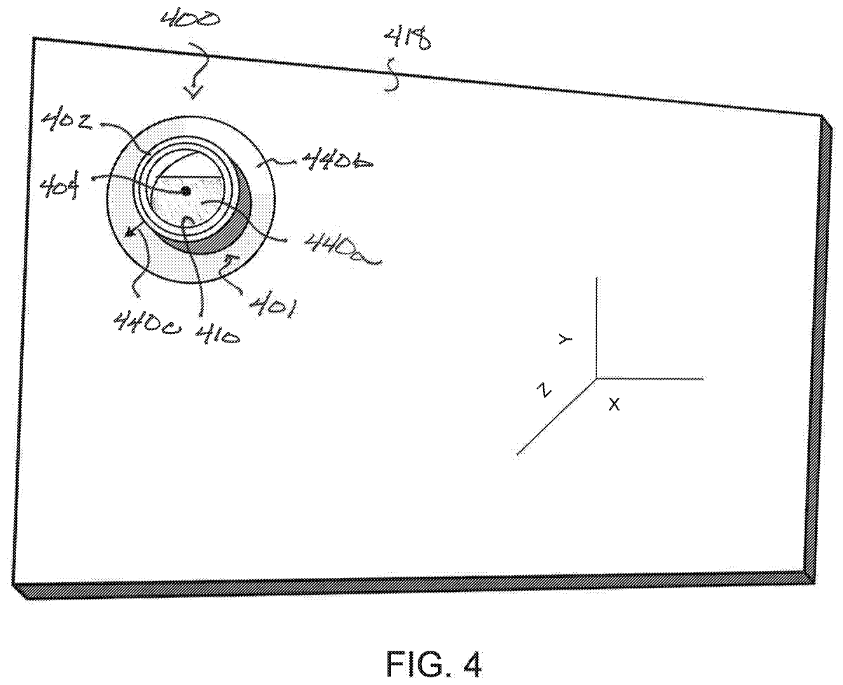

The displayed image on the glass panel 118 can provide visual feedback of the status of a feature that is controlled with the switch 100 (as illustrated in embodiment of FIG. 4) Further, additional elements (not shown) may also be added to the control knob 102 to provide tactile feedback to the user. One skilled in the art would be able to determine the desired feedback mechanism for a particular application of the control knob 102.

Those of ordinary skill in the art should also recognize that the components shown in the exploded view of FIG. 2 are sized and shaped such that when they are assembled together, a compact panel-mounted switch 100 shown in cross section in FIG. 1 is realized. The components shown in FIG. 1 and FIG. 2 thus provide an electronic switch that the action of which emulates a conventional mechanical switch insofar as its tactile feedback to a user.

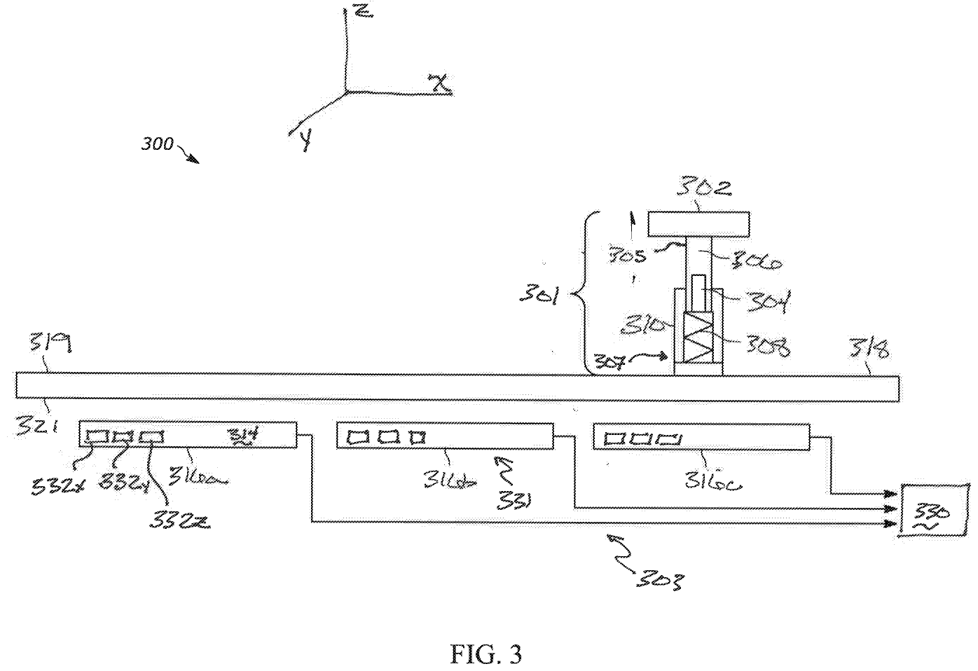

FIG. 3 is a cut-away view of a second embodiment of a switch 300 for use with a glass panel 318. The switch 300 is comprised of a knob 302, a magnet 304 mounted on a shaft 306, a spring 308 between the shaft 306 and a housing 310. A printed circuit board (PCB) 314 which includes a sensor 316a-n, specifically a Hall effect sensor. The switch 300 is mounted to a glass panel 318 by means of a removable mechanical attachment, such as a suction cup, not shown. The arrangement and operation of the switch 300 are explained in greater detail below.

The knob 302 fits onto a first end 305 of the elongated shaft 306 using any conventional apparatus or method. A second or opposite end 307 of the shaft 306 is provided with the permanent magnet 304. The magnet 304 is applied to the second end 307 of the shaft 306 using an adhesive or mechanical attachment mechanism.

The switch 300 is arranged in such a manner that the switch input elements are located on a first side 319 and assembled into a knob assembly 301 and the sensing elements are located on a second side 321 at proximately the same position on the panel 318 and are assembled into a sensor assembly 303. However, the knob assembly and the sensor assembly on either side of the panel 318 do not need to be in contact with one another, thus an opening in the panel 318 is not necessary. Further, the sensor assembly 303 of the switch 300 such that one knob assembly 301 can be used at multiple locations on the panel 318, as described in detail below.

The display panel 318 is illustrated with the switch 300 having the knob assembly located on a top side 319 of the panel 318. Three Hall-effect sensors 316a-n are located on the opposite bottom side 321 and are connected to a microprocessor 330. The switch does not extend through the panel 318 but is instead on one side of the panel that is opposite the side where the sensors 316a-n are located.

The shaft 306 is capable of vertical displacement along its axis of rotation. The shaft 306 has one or more magnets 304 attached to the end of the shaft 306 that is closest to one or more Hall-effect sensors, 316a-n, preferably embodied as 3-D magnetic sensors. Since the panel 318 is made of a non-ferrous or dielectric material, magnetic fields from a magnet attached to the shaft 306 are able to pass through the panel 318.

A coil spring 308 is located inside the housing 310 and around the shaft 306. The spring is compressed such that it biases the shaft 306 (and knob 302) upwardly, i.e., away from the sensors 316a-n. Depressing the shaft 306 downward changes the magnetic field provided to the sensors 316a-n, which causes them to generate a corresponding signal. Output signals from the sensors 316a-n are provided to a processor via a conventional bus, which is a device well-known to those of ordinary skill as two or more electrically-parallel conductors that carry signals around a computer device and its peripheral equipment. Vertical and rotational movement of the shaft, and magnets attached to it, thus provide output signals from the sensors 316a-n, which can be used to control virtually any type of electronic or electrical device. Rotation of the knob 102 thus generates an electrical signal from the Hall-effect sensor 116 that can be used to control some external device. The signals from the Hall-effect sensor 116 are pulses, the rotation of the knob 102 thus effectively produces a signal essentially the same as that which would be provided by a mechanical switch.

The Hall-effect sensors 316a-n comprises an application specific integrated circuit (ASIC) 331 on the PCB 314 which includes up to three Hall-effect cells 332x, 332y, 332z. The Hell-effect cells are arranged in perpendicular orientation from one another such that can sense movement along the X,Y and Z-axes as shown. Therefore, as the control knob 302 is rotated about the z-axis the first two Hall-effect cells 332x, 332y can detect that movement based on the position of the magnet 304 in the X, Y planes. Additionally, when pressure is applied to the control knob 302 the spring 308 flexes allowing the knob 302 and magnet 304n to translate along the Z-axs which can be sensed by the third Hall-effect cell 332z. Thus, the Hall-effect sensor 316a-n can sense motion of the control knob 302 in three dimensions.

The sensor assembly 303 may include multiple Hall-effect sensors 316a-n arranged in an array on the bottom side 321 of the glass panel 318. The knob assembly 301 can than be located on the first side of the panel 318 at a position that corresponds to one of the Hall-effect sensors 316a-n. Therefore, the control knob 302 may be placed in one of a plurality of different locations according the preference of the user.

Additionally, a plurality of first sub-assemblies 301 could be provided where each of them having a variance in the magnet 304 or have some sort of magnetic coating applied such that each of the first sub-assemblies 301 provide a magnetic field having a unique signature that can be detected by the sensors 316a-n. Therefore, the sensors can detect which knob assembly is located at which position on the panel 318 and can vary the visually feedback accordingly.

The displayed image on the panel 318 can provide visual feedback of the status of a feature that is controlled with the switch 300 (as illustrated in embodiment of FIG. 4) Further, additional elements (not shown) may also be added to the control knob 302 to provide tactile feedback to the user. One skilled in the art would be able to determine the desired feedback mechanism for a particular application of the control knob 302. The switch 300 provides an electronic switch that the action of which emulates a conventional mechanical switch insofar as its tactile feedback to a user.

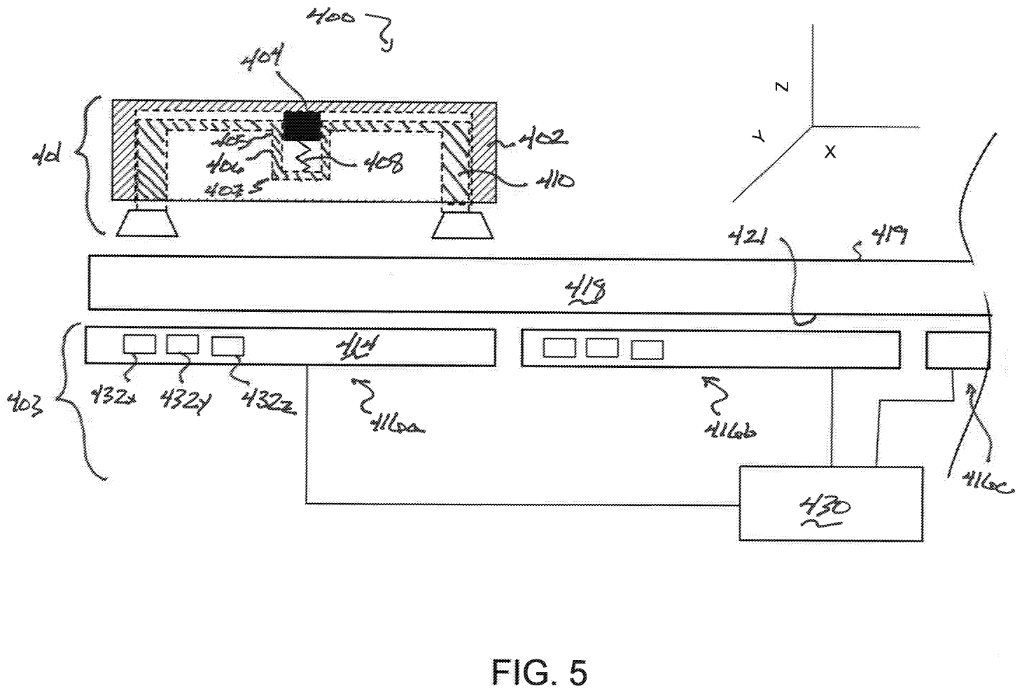

FIGS. 4 and 5 illustrate a third embodiment of a switch 400 for use with a panel 418 on which an image is displayed. The switch 400 is comprised of a knob 402, a magnet 404 mounted on a shaft 406, a spring 408 between the shaft 406 and a housing 410. A printed circuit board (PCB) 414 which includes a sensor 416a-n, specifically a Hall effect sensor. The switch 400 is mounted to a glass panel 418 by means of a removable mechanical attachment, such as a suction cup 434. Other means of removeable mechanical attachment may also be used. One skilled in the art would be able to determine the type of mechanical attachment for a particular application. The arrangement and operation of the switch 400 is explained in greater detail below.

The knob 402 fits onto a first end 405 of the elongated shaft 406 using any conventional apparatus or method. A second or opposite end 407 of the shaft 406 is provided with the permanent magnet 404. The magnet 404 is applied to the second end 407 of the shaft 406 using an adhesive or mechanical attachment mechanism.

The switch 400 is arranged in such a manner that the switch input elements are located on a first side 419 and assembled into a knob assembly 401 and the sensing elements are located on a second side 421 at proximately the same position on the panel 418 and are assembled into a sensor assembly 403. However, the knob assembly 401 403 and the sensor assembly on either side of the panel 418 do not need to be in contact with one another, thus an opening in the panel 418 is not necessary. Further, the sensor assembly 403 of the switch 400 can be arranged such that one knob assembly 401 can be used at multiple locations on the panel 418, as described in detail below.

The display panel 418 is illustrated with the switch 400 having the knob assembly 401 located on a top side 419 of the panel 418. Three Hall-effect sensors 416a-n are located on the opposite bottom side 421 and are connected to a microprocessor 430. The switch does not extend through the panel 418 but is instead on one side of the panel that is opposite the side where the sensors 416a-n are located. The control knob 102, housing 410 and shaft 406 of the knob assembly 401 may be made from transparent materials, such that the display screen can be viewed through the switch 400. The magnet 404 may be sized as small as possible to provide sufficient detectable magnetic field while minimizing the portion of the display that is blocked to sight. The spring may be arranged to align with the magnet to not provide further impediment to view of the display, or may be arranged in another location which minimizes impediment to view of the display.

The shaft 406 is capable of vertical displacement along its axis of rotation. The shaft 406 has one or more magnets 404 attached to the end of the shaft 406 that is closest to one or more Hall-effect sensors, 416a-n, preferably embodied as 3-D magnetic sensors. Since the panel 418 is made of a non-ferrous or dielectric material, magnetic fields from a magnet attached to the shaft 406 are able to pass through the panel 418.

A coil spring 408 is located inside the housing 410 and around the shaft 406. The spring is compressed such that it biases the shaft 406 (and knob 402) upwardly, i.e., away from the sensors 416a-n. Depressing the shaft 406 downward changes the magnetic field provided to the sensors 416a-n, which causes them to generate a corresponding signal. Output signals from the sensors 416a-n are provided to a processor via a conventional bus, which is a device well-known to those of ordinary skill as two or more electrically-parallel conductors that carry signals around a computer device and its peripheral equipment. Vertical and rotational movement of the shaft, and magnets attached to it, thus provide output signals from the sensors 416a-n, which can be used to control virtually any type of electronic or electrical device. Rotation of the knob 102 thus generates an electrical signal from the Hall-effect sensor 116 that can be used to control some external device. The signals from the Hall-effect sensor 116 are pulses, the rotation of the knob 102 thus effectively produces a signal essentially the same as that which would be provided by a mechanical switch.

The Hall-effect sensors 416a-n comprises an application specific integrated circuit (ASIC) 431 on the PCB 414 which includes up to three Hall-effect cells 432x, 432y, 432z. The Hell-effect cells are arranged in perpendicular orientation from one another such that can sense movement along the X,Y and Z-axes as shown. Therefore, as the control knob 402 is rotated about the z-axis the first two Hall-effect cells 432x, 432y can detect that movement based on the position of the magnet 404 in the X, Y planes. Additionally, when pressure is applied to the control knob 402 the spring 408 flexes allowing the knob 402 and magnet 404n to translate along the Z-axis which can be sensed by the third Hall-effect cell 432z. Thus, the Hall-effect sensor 416a-n can sense motion of the control knob 402 in three-dimensions.

The sensor assembly 403 may include multiple Hall-effect sensors 416a-n arranged in an array on the bottom side 421 of the panel 418. The knob assembly 401 can then be located on the first side of the panel 418 at a position that corresponds to one of the Hall-effect sensors 416a-n. Therefore, the control knob 402 may be placed in one of a plurality of different locations according the preference of the user.

Additionally, a plurality of first sub-assemblies 401 could be provided where each of them having a variance in the magnet 404 or have some sort of magnetic coating applied such that each of the first sub-assemblies 401 provide a magnetic field having a unique signature that can be detected by the sensors 416a-n. Therefore, the sensors can detect which knob assembly is located at which position on the display panel 418 and can vary the visually feedback accordingly.

The displayed image on the panel 418 can provide visual feedback of the status of a feature that is controlled with the switch 400. For example, the display may show an indicator 440a, 440b as color rendering, shown at ¾, which illustrates the current status of the feature being controlled, e.g volume is at ¾. Alternatively, the display may be an arrow or other indicator 440b that rotates in a clock-wise or counter-clockwise manner about the center of the switch 400. The indicator 440a-c may be visually displayed on the inside of the switch as illustrated by indicator 440a or may be displayed on the outside of the switch 400 as illustrated by indicators 440b, 440b. The display may also show a guide (not shown) of where the knob assembly 301 should be attached to the panel 418 to assist in alignment of the knob assembly 301 with the sensor assembly 303.

As described above, multiple first sub-assemblies can be used at once and detected from one another, the display may adjust the style of indicator 440a-c based upon the style of knob assembly attached, e.g. knob assembly 301 and knob assembly 401 would both be used on the same panel 318,418.

Further, additional elements (not shown) may also be added to the control knob 402 to provide tactile feedback to the user. One skilled in the art would be able to determine the desired feedback mechanism for a particular application of the control knob 402. The switch 400 provides an electronic switch that the action of which emulates a conventional mechanical switch insofar as its tactile feedback to a user.

The switch 400 illustrated uses a rotary knob input, however other styles of mechanical switches may also be used for the knob assembly 401, for example, joysticks, dials, slider bars, rollerballs, etc. One skilled in the art would be able to apply the switch 400 as taught herein to different styles of knob assemblies.

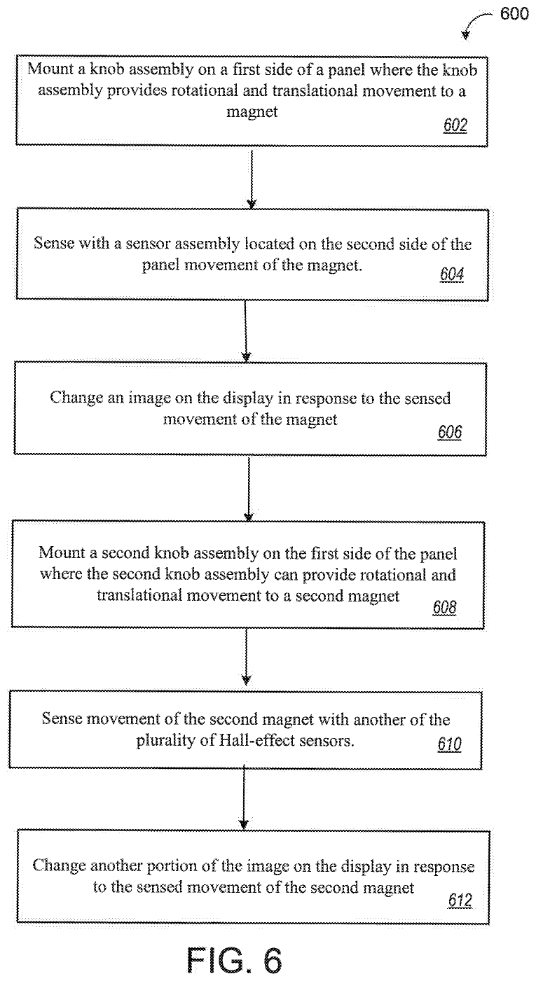

FIG. 6 illustrates an exemplary method 600 of using a switch 100, 300, 400 to provide control for an electronic display including: mounting a knob assembly 301,401 on a first side 319,419 of a panel 318, 418 where the knob assembly 301, 401 can provide rotational and translational movement to a magnet 304, 404, shown at 602. Sensing with a sensor assembly 303, 403 located on the second side 321, 421 of the panel 318, 418 movement of the magnet 304, 404 using at least one hall-effect sensor 316a-n, 416a-n adjacent the panel where the knob assembly 301, 401 is mountable to the panel 318, 418 such that the at least one hall-effect sensor 316a-n, 416a-n is located inside the magnetic field created by the magnet 304,404, shown at 604. Changing an image on the display in response to the sensed movement of the magnet 304, 404, shown at 606.

Implementations may include one or more of the following features. The method where the at least one hall-effect sensor 316a-n, 416a-n includes three hall-effect cells 332x-z, 432x-z arranged in a perpendicular manner to one another.

The method where the at least one hall-effect sensor 316a-n, 416a-n is a plurality of hall-effect sensors 316a-n, 416a-n arranged in an array on the second side 321, 421 of the panel 318, 418 such that the knob assembly 301, 401 may be positioned proximate to one of the plurality of hall-effect sensors 316a-n,416a-n.

The method further including: mounting a second knob assembly 301, 401 on the first side 319, 419 of the panel 318, 418 where the second knob assembly 301,401 can provide rotational and translational movement to a second magnet 304, 404, shown at 608. Sensing movement of the second magnet304, 404 with another of the plurality of hall-effect sensors 316a-n,416a-n, shown at 610.

The method further including changing another portion of the image on the display in response to the sensed movement of the second magnet 304, 404, shown at 612.

The method further including sensing a difference between the magnetic field produced by the first magnet 304, 440and the magnetic field produced by a second magnet 304, 404.

The method further including removably securing the housing 310, 410 to the first side 319, 419 of the panel 318, 418. The switch 300, 400 where the shaft 306, 406 is configured to translate along an axis of the shaft 306, 306.

While this specification contains many specifics, these should not be construed as limitations on the scope of the disclosure or of what may be claimed, but rather as descriptions of features specific to particular implementations of the disclosure. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multi-tasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

A number of implementations have been described. Nevertheless, it will be understood that various modifications may be made without departing from the spirit and scope of the disclosure. Accordingly, other implementations are within the scope of the following claims. For example, the actions recited in the claims can be performed in a different order and still achieve desirable results.

What is claimed is:

1. A switch comprising:
a dielectric panel having first and second sides;
a knob assembly mounted on the first side of the panel, the knob assembly comprising:
a housing having first and second ends;
a knob rotatably and translationally mounted to the housing at the first end;
a shaft attached to the knob at a first end; and
a permanent magnet attached to a second end of the shaft such that rotation of and translation of the knob produces a corresponding motion of the magnet; and
a sensor assembly located on the second side of the panel, the sensor assembly comprising at least one Hall-effect sensor adjacent the panel; and
wherein the knob assembly is mounted to the panel such that the at least one Hall-effect sensor is located inside the magnetic field created by the magnet.

2. The switch of claim 1, wherein the at least one Hall-effect sensor comprises three Hall-effect cells arranged in a perpendicular manner to one another.

3. The switch of claim 1, wherein the at least one Hall-effect sensor is a plurality of Hall-effect sensors arranged in an array on the second side of the panel such that the knob assembly may be positioned proximate to one of the plurality of Hall-effect sensors.

4. The switch of claim 3, further comprising a second knob assembly mounted on the first side of the panel, the second knob assembly comprising:
a second housing having first and second ends;
a second knob rotatably and translationally mounted to the second housing at the first end;
a second shaft attached to the second knob at a first end; and
a second permanent magnet attached to a second end of the second shaft such that rotation of and translation of the second knob produces a corresponding motion of the second magnet; and
wherein the second knob assembly is mounted to the panel such that another of the plurality of Hall-effect sensors is located inside the magnetic field created by the magnet of the second knob assembly.

5. The switch of claim 1, wherein the second magnet has a different magnetic strength than the first magnet.

6. The switch of claim 1, wherein the housing for the knob assembly is removeably secured to the first side of the panel.

7. The switch of claim 1, wherein the shaft is configured to translate along an axis of the shaft.

8. The switch of claim 6, further comprising a coil spring inside the housing and around the shaft, the spring providing a bias force to the shaft, which holds the magnet away from the Hall-effect sensor.

9. A method of providing control for an electronic display comprising:
mounting a knob assembly on a first side of a panel wherein the knob assembly can provide rotational and translational movement to a magnet;
sensing with a sensor assembly located on the second side of the panel movement of the magnet using at least one Hall-effect sensor adjacent the panel
wherein the knob assembly is mountable to the panel such that the at least one Hall-effect sensor is located inside the magnetic field created by the magnet; and
changing an image on the display in response to the sensed movement of the magnet.

10. The method of claim 8, wherein the at least one Hall-effect sensor comprises three Hall-effect cells arranged in a perpendicular manner to one another.

11. The method of claim 8, wherein the at least one Hall-effect sensor is a plurality of Hall-effect sensors arranged in an array on the second side of the panel such that the knob assembly may be positioned proximate to one of the plurality of Hall-effect sensors.

12. The method of claim 11, further comprising:
mounting a second knob assembly on the first side of the panel wherein the second knob assembly can provide rotational and translational movement to a second magnet;
sensing movement of the second magnet with another of the plurality of Hall-effect sensors.

13. The method of claim 11, further comprising changing another portion of the image on the display in response to the sensed movement of the second magnet.

14. The method of claim 11, further comprising sensing a difference between the magnetic field produced by the first magnet and the magnetic field produced by a second magnet.

15. The method of claim 8, further comprising removeably securing the housing to the first side of the panel.
